(19) United States
(12) Patent Application Publication
(10) Pub. No.: US 2019/0006917 A1
(43) Pub. Date: Jan. 3, 2019

(54) INTERFERENCE-SHIELDING HALL PLATE

(71) Applicant: DongChang Motor (Shenzhen) Co., Ltd., Shenzhen, Guangdong (CN)

(72) Inventors: Gao Chen, Shenzhen, Guangdong (CN); Ru Wang, Shenzhen, Guangdong (CN)

(21) Appl. No.: 15/737,753

(22) PCT Filed: Dec. 30, 2016
(86) PCT No.: PCT/CN2016/113633

§ 371 Date: Dec. 18, 2017

(30) Foreign Application Priority Data
Dec. 13, 2016 (CN) 201611146249.9

(51) Int. Cl. H02K 11/01; H02K 11/215; H05K 9/00; G01D 5/14

(52) U.S. Cl. CPC H02K 11/01; G01D 5/145; H05K 9/00; H02K 11/215

(57) ABSTRACT

An interference-shielding Hall plate (100) includes a shielding plate (10) and a Hall plate body (20). A first Hall sensor (210) is provided on a first surface (201) of the Hall plate body to detect magnet position of a motor, and a second Hall sensor (220) is provided on a second surface (202) of the Hall plate body to detect magnet position of an external device that cooperates with the motor. The shielding plate is welded to the Hall plate body to avoid influence of the magnet of a motor body on the second Hall sensor and interference of the magnet of an external device, which cooperates with the motor, on the first Hall sensor. Without affecting detection of the position of the motor body magnet, the motor can operate normally.

### TECHNICAL FIELD

The present disclosure relates to a Hall plate, and in particular to an interference-shielding Hall plate of a motor.

### BACKGROUND

Nowadays, most of the rechargeable electric tool industries use traditional brush motor as a power source. However, the traditional brush motor has low efficiency, short life and great electromagnetic interference. The new brushless motor has high efficiency, long life, high speed operation and small electromagnetic interference. Therefore, with the continuous development of motor and electronic technology, brushless motors will gradually replace brush motors and become the mainstream products in the motor market. In order to achieve the function of commutation and detection of the motor magnet position, brushless motor will use switching-type Hall sensor for digital output to sense the characteristics of the motor body magnet. At the same time, using the switching-type Hall sensor for digital output can carry out detection of magnet position of the external device that cooperates with the motor. However, the magnet on the motor body will affect the Hall sensor that is used to detect the magnet position of an external device that cooperates with the motor. At the same time, the magnet of the external device that cooperates with the motor will affect the Hall sensor for detecting the motor magnet position. This results in detection error of the Hall sensors, thereby causing inconvenience of usage to the users, and affecting normal operation of the motor.

Accordingly, there is need to provide an interference-shielding Hall plate to overcome the above-mentioned defects.

### SUMMARY

The technical problem to be solved by the present disclosure is to provide an interference-shielding Hall plate which can effectively avoid interference of magnets of a motor body and an external device, which cooperates with the motor, on the Hall sensors of the Hall plate.

To achieve the above object, the present disclosure provides an interference-shielding Hall plate including a Hall plate body, the Hall plate body having a first surface and a second surface opposite to the first surface; a first Hall sensor provided on the first surface to detect magnet position of a motor; a second Hall sensor provided on the second surface to detect magnet position of an external device that cooperates with the motor; and a shielding plate, the shielding plate being provided on the first surface of the Hall plate body, and covering a region opposite to a position where the second Hall sensor is located.

The second Hall sensor is provided to sense the characteristics and the position of the magnet of an external device, which cooperates with the motor, in order to facilitate the usage of motor by the user, as well as the implementation of commutation of the motor. The shielding plate can shield the external interference on the first Hall sensor and the second Hall sensor. The motor body rotor is a permanent magnet, i.e. the motor body rotor is a motor body magnet. It has magnetic interference on the second Hall sensor, and it determines the position of the motor body magnet. As such, the shielding plate is disposed in a region opposite to the position where the second Hall sensor is located. This is beneficial in that it can shield the interference of the magnet of the motor body on the second Hall sensor and can facilitate usage by the user.

In a further technical solution, the shielding plate includes a shielding plate body; and a plurality of solder pins provided on the shielding plate body, and wherein a plurality of engaging openings is provided on the Hall plate body and corresponds to the plurality of solder pins, the solder pins being engaged in the engaging openings and attached to the Hall plate body by soldering. Magnetic continuity needs to be maintained when using a cover to form a shield body. The magnetic continuity of the shield body can be maintained through soldering. Maintaining the magnetic continuity between surfaces can ensure that the magnetic lines of force can advance along its low magneto-resistance path to thereby improve the shielding effect.

In a further technical solution, the Hall plate body is ring-shaped and the shielding plate body is arc-shaped, and an inner edge of the shielding plate body is flush with an edge of a central opening of the Hall plate body.

In a further technical solution, three first Hall sensors are provided on the first surface of the Hall plate body, and the three first Hall sensors are evenly distributed along the edge of the central opening of the Hall plate body.

In a further technical solution, two of the first Hall sensors are disposed in close proximity to two ends of the shielding plate body respectively.

In a further technical solution, three second Hall sensors are provided on the second surface of the Hall plate body, and the three second Hall sensors are evenly distributed along a peripheral edge of the Hall plate body.

In a further technical solution, the shielding plate body has four solder pins, wherein two of the solder pins are provided on edges of the two ends of the shielding plate body respectively, and another two of the solder pins are provided at intervals along an outer edge of the shielding plate body. The arrangement of four solder pins can facilitate the securing of the connection between the shielding plate and the Hall plate body. It can make the connection between the shielding plate and the Hall plate body closer and can avoid an increase in production cost by using too many solder pins.

In a further technical solution, glue is provided along joining edges of the Hall plate body and the shielding plate body for sealing purposes. Sealing of the joining edges by glue is beneficial in that it can reduce air gaps so that the Hall plate and the shielding plate can be tightly joined together to thereby enhance the shielding effect.

In a further technical solution, the shielding plate is formed by stamping or cutting of a cold-rolled steel plate. Cold-rolled steel plate possesses better permeability property and better punching characteristics, making it easier to process. It can also lower the production cost.

In a further technical solution, an area occupied by the shielding plate is not less than 60% of an area of the first surface of the Hall plate body.

The present disclosure has the following beneficial effects as compared with the prior art. The interference-shielding Hall plate of the present disclosure is provided with a shielding plate mounted on a Hall plate body, and the position of the shielding plate is specially designed so that it is located on the same side as the first Hall sensor for detecting the position of the magnet of the motor, and it is covering a region opposite to the position where the second Hall sensor is located. This can effectively shield the interference of the magnet of the motor body on the second Hall sensor, and at the same time shield the interference of the magnet of the external device, which cooperates with the motor, on the first Hall sensor, thereby rendering normal operation of the motor and facilitating usage by the users.

The present disclosure will become more apparent from the following description, which is used to explain the embodiments of the present disclosure, when taken in conjunction with the accompanying drawings.

### BRIEF DESCRIPTION OF THE DRAWINGS

FIG. 1 is a perspective view of an interference-shielding Hall plate according to an embodiment of the present disclosure.

FIG. 2 is a perspective view of a shielding plate of the interference-shielding Hall plate of FIG. 1.

FIG. 3 is a perspective view of a back structure of the interference-shielding Hall plate of FIG. 1.

### DETAILED DESCRIPTION

The technical solution provided by the embodiments of the interference-shielding Hall plate will be described clearly and completely below in conjunction with the drawings, wherein like parts are designated by like numerals throughout. It is apparent that the described embodiments are only some embodiments of the interference-shielding Hall plate, and are not intended to be exhaustive. All other embodiments obtained by an ordinary technical person skilled in the art, without making any creative effort, are within the scope of protection of the interference-shielding Hall plate of the present disclosure.

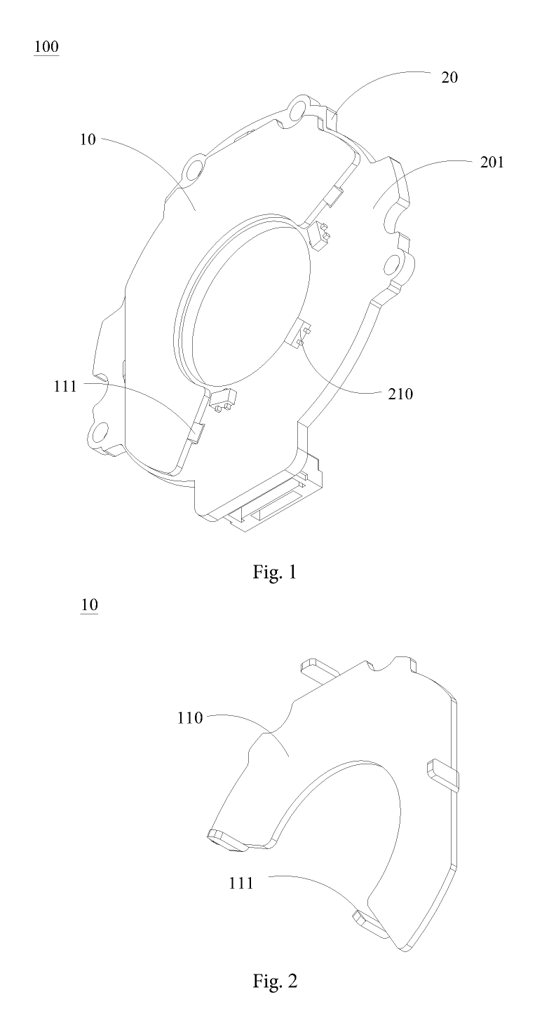

Referring to FIG. 1, the interference-shielding Hall plate 100 of the present disclosure may include a Hall plate body 20 and a shielding plate 10. The Hall plate body 20 may include a first surface 201 and a second surface 202 opposite to the first surface 201. A first Hall sensor 210 may be provided on the first surface 201 to detect the magnet position of a motor. A second Hall sensor 220 may be provided on the second surface 202 to detect the magnet position of an external device which cooperates with the motor. The shielding plate 10 may be provided on the first surface 201 of the Hall plate body 20, and covering a region opposite to the position where the second Hall sensor 220 is located.

The second Hall sensor 220 can be provided to sense the characteristics and the position of the magnet of an external device that cooperates with the motor in order to facilitate the use of motor by the user, as well as the implementation of commutation of the motor. The shielding plate 10 can shield the external interference on the first Hall sensor 210 and the second Hall sensor 220. The motor body rotor is a permanent magnet, i.e. the motor body rotor is a motor body magnet. It has magnetic interference on the second Hall sensor 220, and it determines the position of the motor body magnet. As such, the shielding plate 10 is disposed in a region opposite to the position where the second Hall sensor 220 is located. This is beneficial in that it can shield the interference of the magnet of the motor body on the second Hall sensor 220 and can facilitate usage of the motor by the user.

In combination with FIG. 2, in some embodiments such as the present embodiment, the shielding plate 10 may include a shielding plate body 110, and four solder pins 111 may be provided on the shielding plate body 110. Engaging openings may be provided on the Hall plate body 20 that correspond to the solder pins 111. The solder pins 111 can be engaged in the engaging openings and attached to the Hall plate body 20 by soldering.

The arrangement of four solder pins 111 can facilitate the securing of the connection between the shielding plate 10 and the Hall plate body 20. It can make the connection between the shielding plate 10 and the Hall plate body 20 closer and can avoid an increase in production cost by using too many solder pins. Magnetic continuity needs to be maintained when using a cover to form a shield body. The magnetic continuity of the shield body can be maintained through soldering. Maintaining the magnetic continuity between surfaces can ensure that the magnetic lines of force can advance along its low magneto-resistance path to thereby improve the shielding effect.

Referring to FIG. 1, in some embodiments such as the present embodiment, the Hall plate body 20 may be ring-shaped, and the shielding plate body 110 may be arc-shaped. An inner edge of the shielding plate body 110 may be flush with an edge of a central opening of the Hall plate body 20.

In some embodiments such as the present embodiment, three first Hall sensors 210 may be provided on the first surface 201 of the Hall plate body 20. The three first Hall sensors 210 may be evenly distributed along the edge of the central opening of the Hall plate body 20. Two of the first Hall sensors 210 may be disposed in close proximity to the two ends of the shielding plate body 110 respectively.

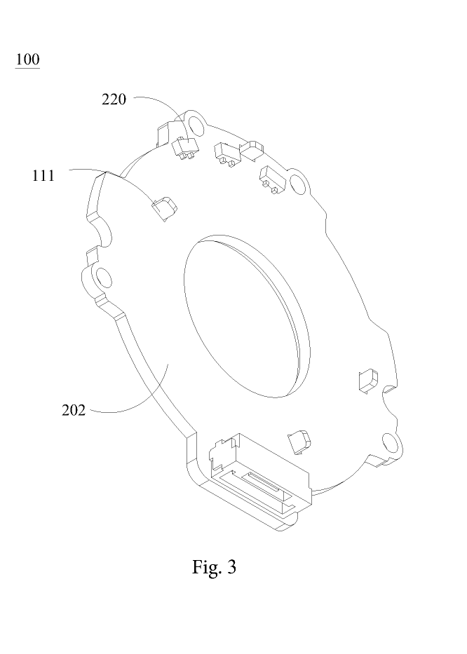

Referring to FIG. 3, in some embodiments such as the present embodiment, three second Hall sensors 220 may be provided on the second surface 202 of the Hall plate body 20. The three second Hall sensors 220 may be evenly distributed along a peripheral edge of the Hall plate body 20.

Referring to FIGS. 1 and 2, in some embodiments such as the present embodiment, two of the solder pins 111 may be provided on the edges of the two ends of the shielding plate body 110 respectively. Another two of the solder pins 111 may be provided at intervals along an outer edge of the shielding plate body.

In some embodiments such as the present embodiment, the joining edges of the Hall plate body 20 and the shielding plate body 10 may be provided with glue for sealing the joining edges. Sealing of the joining edges by glue is beneficial in that it can reduce air gaps so that the Hall plate and the shielding plate can be tightly joined together to thereby enhance the shielding effect.

In some embodiments such as the present embodiment, the shielding plate 10 may be formed by stamping or cutting of a cold-rolled steel plate. Cold-rolled steel plate possesses better permeability property and better punching characteristics, making it easier to process. It can also lower the production cost.

In some embodiments such as the present embodiment, the area occupied by the shielding plate 10 is not less than 60% of the area of the first surface 201 of the Hall plate body 20. This arrangement is beneficial in that it can enhance the shielding effect so that shielding of interference can be more fully performed.

In summary, the interference-shielding Hall plate of the present disclosure is provided with a shielding plate mounted on a Hall plate body, and the position of the shielding plate is specially designed so that it is located on the same side as the first Hall sensor for detecting the position of the magnet of the motor, and is covering the region opposite to the position where the second Hall sensor is located. This can effectively shield the interference of the magnet of the motor body on the second Hall sensor, and also shield the interference of the magnet of the external device, which cooperates with the motor, on the first Hall sensor, thereby rendering normal operation of the motor and facilitating usage by the users.

The present disclosure has been described above in connection with the preferred embodiments. However, the present disclosure is not limited to the above disclosed embodiments. Instead, various modifications and equivalent combinations according to the essence of the present disclosure are also covered.

1. An interference-shielding Hall plate, comprising:
a Hall plate body, the Hall plate body comprising a first surface and a second surface opposite to the first surface;
a first Hall sensor provided on the first surface to detect magnet position of a motor;
a second Hall sensor provided on the second surface to detect magnet position of an external device which cooperates with the motor; and
a shielding plate, the shielding plate being provided on the first surface of the Hall plate body, and covering a region opposite to a position where the second Hall sensor is located.

2. The interference-shielding Hall plate as claimed in claim 1, wherein the shielding plate comprises a shielding plate body; and a plurality of solder pins provided on the shielding plate body, and wherein a plurality of engaging openings is provided on the Hall plate body and corresponds to the plurality of solder pins, the solder pins being engaged in the engaging openings and attached to the Hall plate body by soldering.

3. The interference-shielding Hall plate as claimed in claim 2, wherein the Hall plate body is ring-shaped and the shielding plate body is arc-shaped, and an inner edge of the shielding plate body is flush with an edge of a central opening of the Hall plate body.

4. The interference-shielding Hall plate as claimed in claim 3, wherein three first Hall sensors are provided on the first surface of the Hall plate body, and the three first Hall sensors are evenly distributed along the edge of the central opening of the Hall plate body.

5. The interference-shielding Hall plate as claimed in claim 4, wherein two of the first Hall sensors are disposed in close proximity to two ends of the shielding plate body respectively.

6. The interference-shielding Hall plate as claimed in claim 3, wherein three second Hall sensors are provided on the second surface of the Hall plate body, and the three second Hall sensors are evenly distributed along a peripheral edge of the Hall plate body.

7. The interference-shielding Hall plate as claimed in claim 3, wherein two of the solder pins are provided on edges of the two ends of the shielding plate body respectively, and another two of the solder pins are provided at intervals along an outer edge of the shielding plate body.

8. The interference-shielding Hall plate as claimed in claim 1, wherein glue is provided along joining edges of the Hall plate body and the shielding plate body for sealing the joining edges.

9. The interference-shielding Hall plate as claimed in claim 1, wherein the shielding plate is formed by stamping or cutting of a cold-rolled steel plate.

10. The interference-shielding Hall plate as claimed in claim 1, wherein an area occupied by the shielding plate is not less than 60% of an area of the first surface of the Hall plate body.

11. The interference-shielding Hall plate as claimed in claim 2, wherein an area occupied by the shielding plate is not less than 60% of an area of the first surface of the Hall plate body.

12. The interference-shielding Hall plate as claimed in claim 3, wherein an area occupied by the shielding plate is not less than 60% of an area of the first surface of the Hall plate body.

13. The interference-shielding Hall plate as claimed in claim 4, wherein an area occupied by the shielding plate is not less than 60% of an area of the first surface of the Hall plate body.

14. The interference-shielding Hall plate as claimed in claim 5, wherein an area occupied by the shielding plate is not less than 60% of an area of the first surface of the Hall plate body.

15. The interference-shielding Hall plate as claimed in claim 6, wherein an area occupied by the shielding plate is not less than 60% of an area of the first surface of the Hall plate body.

16. The interference-shielding Hall plate as claimed in claim 7, wherein an area occupied by the shielding plate is not less than 60% of an area of the first surface of the Hall plate body.

17. The interference-shielding Hall plate as claimed in claim 8, wherein an area occupied by the shielding plate is not less than 60% of an area of the first surface of the Hall plate body.

18. The interference-shielding Hall plate as claimed in claim 9, wherein an area occupied by the shielding plate is not less than 60% of an area of the first surface of the Hall plate body.
